(19) United States
(12) Patent Application Publication
(10) Pub. No.: US 2024/0332828 A1
(43) Pub. Date: Oct. 3, 2024

(54) BUSBAR CONNECTION STRUCTURE

(71) Applicant: HONDA MOTOR CO., LTD., Tokyo (JP)

(72) Inventor: Takahiro HAGIMOTO, Saitama (JP)

(21) Appl. No.: 18/583,883

(22) Filed: Feb. 22, 2024

(30) Foreign Application Priority Data
Mar. 31, 2023 (JP) 2023-057756

(51) Int. Cl. H01R 4/70; H01R 4/34

(52) U.S. Cl. CPC H01R 4/70; H01R 4/34

(57) ABSTRACT

The objective is to render a busbar connection structure compact while allowing the counterforce from a heat transfer sheet pushing back fastened parts to be applied to a fastening part in a well-balanced manner. The busbar connection structure includes a fastening part, fastened parts, and a heat transfer sheet. The fastening part fastens the terminal block body to the cooling section. The first fastened part is a conductor attached to one side of the fastening part in the terminal block body. The connection part of the busbars is fastened to the first fastened part. The second fastened part is a conductor attached to another side of the fastening part. The connection part of the busbar is fastened to the second fastened part. The heat transfer sheet is an insulator interposed between the first fastened part and the cooling section, and between the second fastened part and the cooling section.

This application is based on and claims the benefit of priority from Japanese Patent Application No. 2023-057756, filed on 31 Mar. 2023, the content of which is incorporated herein by reference.

### BACKGROUND OF THE INVENTION

### Field of the Invention

The present invention relates to a busbar connection structure for electrically connecting a plurality of busbars.

### Related Art

Some busbar connection structures enable heat transfer by physically connecting a connection part of a plurality of busbars to a cooling section, while electrically insulating them.
Patent Document 1: Japanese Patent No. 6623392

### SUMMARY OF THE INVENTION

The present inventors have considered using the following busbar connection structure. The busbar connection structure includes a terminal block and a heat transfer sheet. The terminal block includes a terminal block body, a fastened part, and two fastening parts.

The terminal block body is made of an insulator. The two fastening parts fasten the terminal block body to the cooling section at both ends of the terminal block body. The fastened part is a conductor attached to a portion between the two fastening parts of the terminal block body. The connection part of the plurality of busbars are fastened to the fastened part. The heat transfer sheet is an insulator interposed between the fastened part and the cooling section. This allows the connection part of the busbars to be physically connected to the cooling section via the fastened part and the heat transfer sheet and capable of transferring heat to the cooling section. On the other hand, the connection part of the busbars is electrically insulated from the cooling section by the intervening insulating heat transfer sheet.

The inventors have focused on the following problems with this type of busbar connection structure. As the terminal block only has one fastened part, a terminal block is needed for each connection part of the busbars. Moreover, since the terminal block has two fastening parts, two fastening parts are required for each fastened part. On the other hand, if there is only one fastening part, the fastening part will be arranged only on one side of the fastened part. Consequently, the counterforce from the heat transfer sheet pushing back the fastened part will only be applied from one side to the fastening part. This may result in an imbalance of the counterforces on the fastening part, potentially causing the terminal block to tilt or warp.

In light of the above situation, the present invention has been made with the objective of rendering the busbar connection structure compact, while allowing the counterforce from the heat transfer sheet pushing back the fastened parts to be applied to the fasting part in a well-balanced manner.

The present inventors have found that the above objective can be achieved by providing a fastened part on both sides of the fastening parts in the terminal block body, and by interposing heat transfer sheets between each fastened part and the cooling section. The present invention relates to the busbar connection structure as described below in (1) to (3).

(1) A busbar connection structure that electrically connects a plurality of busbars to each other, and connects the connection parts of the busbars to a cooling section in a heat transferable manner while electrically insulating the connection parts of the busbars from a cooling section, in which the busbar connection structure includes:
a terminal block body as an insulator;
a fastening part that fastens the terminal block body to the cooling section;
a first fastened part as a conductor attached to one of both sides of the fastening part in the terminal block body, so as to be exposed to outside of the terminal block body, the first fastened part having the connection part of the plurality of busbars fastened thereto;
a second fastened part as a conductor attached to another of the both sides, so as to be exposed to outside of the terminal block body, the second fastened part having the connection part of the plurality of busbars fastened thereto; and a heat transfer sheet as an insulator interposed between both the first fastened part and the cooling section, and between the second fastened part and the cooling section.

According to this configuration, a single terminal block based on a single terminal block body includes the first and second fastened parts. Therefore, the need for providing a terminal block to each connection part of the busbars is eliminated, resulting in a more compact busbar connection structure.

Moreover, the first and second fastened parts are located on both sides of the fastening parts, and the heat transfer sheet is interposed between the first fastened part and the cooling section as well as between the second fastened part and the cooling section. Therefore, compared to cases where a heat transfer sheet is placed only on one side of the terminal block body, the counterforce from the heat transfer sheet pushing back the fastened parts is applied to the fastening part in a well-balanced manner. This helps prevent the terminal block from tilting or warping.

This configuration makes it possible to render the busbar connection structure compact, while allowing the counterforce from the heat transfer sheet pushing back the fastened parts to be applied to the fasting part in a well-balanced manner.

(2) In the busbar connection structure as described in (1), each of the fastened parts includes a fastened base as a conductor attached to the terminal block body, and a bolt; the fastened base includes a thread hole; and the connection part is fastened to the fastened part by threading the bolt into the thread hole in a state where the bolt is engaged with the connection part.

With this configuration, each fastened part is realized with a simple structure consisting of a fastened base and bolts.

(3) In the busbar connection structure as described in (1), the plurality of busbars include a first busbar, a second busbar, and a third busbar, a tip end of the first busbar and a base end of the second busbar are fastened to the first fastened part, and a tip end of the second busbar and a base end of the third busbar are fastened to the second fastened part.

With this configuration, three busbars can be connected in series using a single terminal block.

The configuration described in (1) makes it possible to render the busbar connection structure compact, while allowing the counterforce from the heat transfer sheet pushing back the fastened parts to be applied to the fasting part in a well-balanced manner. Furthermore, additional effects can be achieved respectively with the configurations described in (2) and (3), which reference (1).

### BRIEF DESCRIPTION OF THE DRAWINGS

FIG. 1 is a perspective view illustrating a busbar connection structure according to a first embodiment;

FIG. 2 is a perspective view illustrating a terminal block of the busbar connection structure;

FIG. 3 is a front sectional view illustrating the busbar connection structure;

FIG. 4 is a perspective view illustrating a terminal block of a first comparative example;

FIG. 5 is a front sectional view illustrating the busbar connection structure; and

FIG. 6 is a front sectional view illustrating a busbar connection structure according to a second comparative example.

### DETAILED DESCRIPTION OF THE INVENTION

Hereinafter, embodiments of the present invention will be described with reference to the drawings. However, the present invention is not limited to the following embodiments and can be implemented with appropriate modifications within the scope that does not deviate from the spirit of the invention.

### First Embodiment

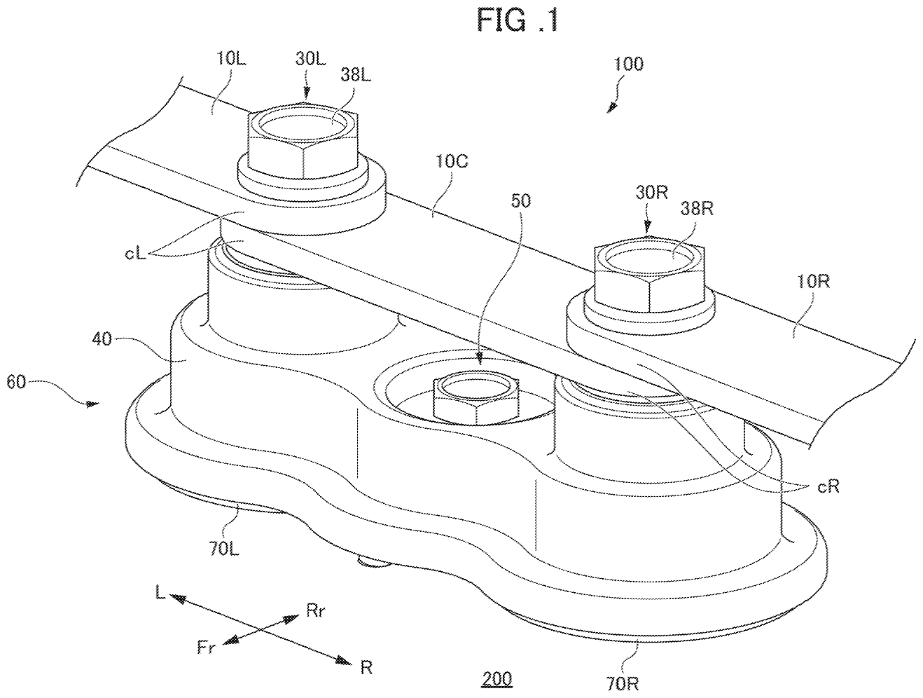

As illustrated in FIG. 1, a busbar connection structure 100 electrically connects busbars 10L, 10C, 10R that transmit power, and also physically connects the connection parts of the busbars to a cooling section 200 to enable heat transfer while electrically insulating them. Each of the busbars 10L, 10C, 10R, and the cooling section 200 are made of a conductor such as metal.

The busbar connection structure 100 includes a terminal block 60 and heat transfer sheets 70L, 70R. Hereinafter, the longitudinal direction of the terminal block 60 is referred to as the “left-right direction L, R”, a predetermined direction perpendicular to the left-right direction L, R is referred to as the “front-back direction Fr, Rr”, and the direction perpendicular to both the left-right direction L, R and the front-back direction Fr, Rr is referred to as the “up-down direction”. Therefore, for example, the aforementioned up-down direction is not limited to the vertical direction and may be a direction diagonal to the vertical direction or may be a horizontal direction.

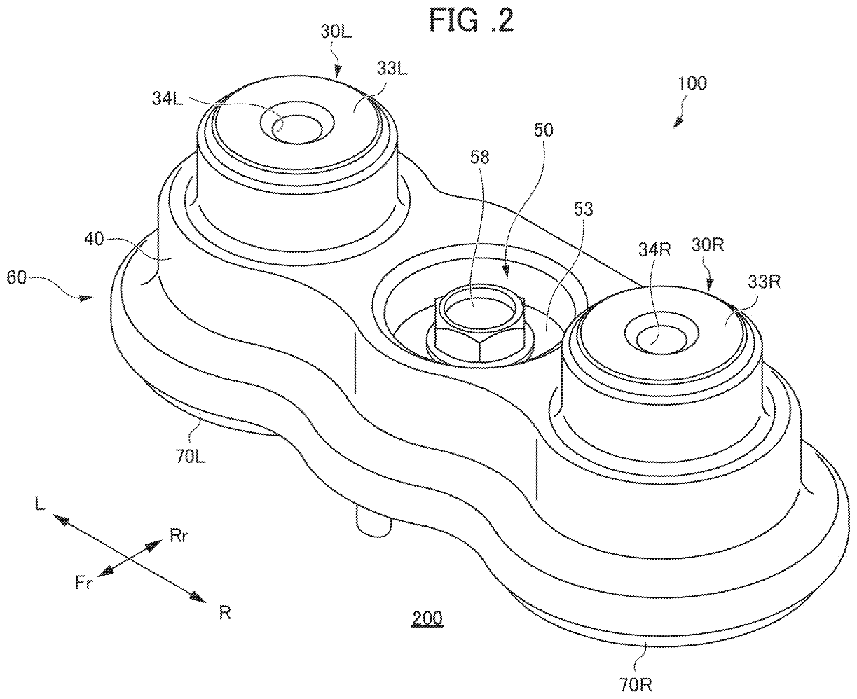

As illustrated in FIG. 2, the terminal block 60 includes a terminal block body 40, a fastening part 50, and two fastened parts 30L, 30R. The terminal block body 40 is made of an insulator such as resin and extends in the left-right direction L, R.

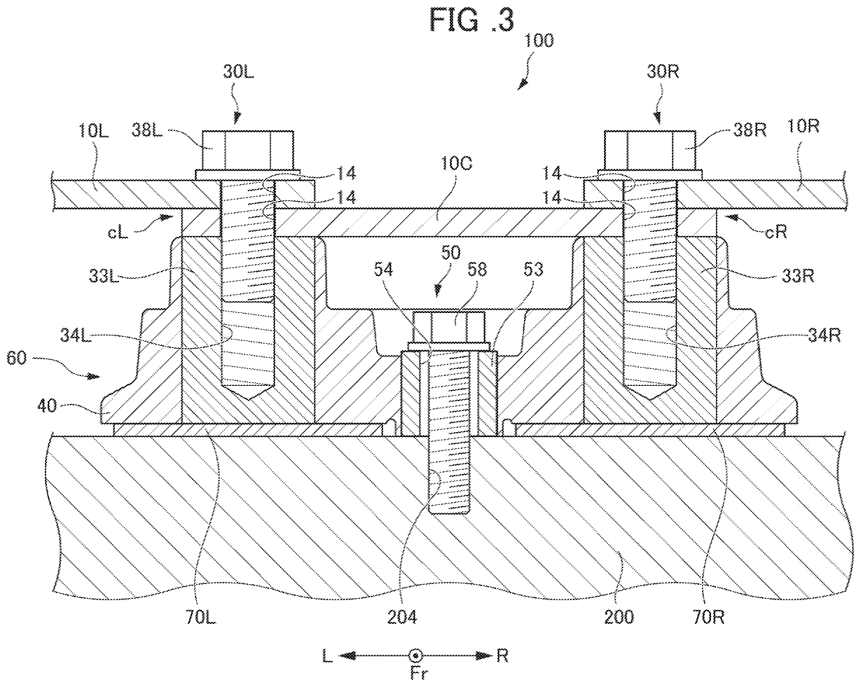

The fastening part 50 is configured to be capable of fastening the central part in the left-right direction L, R of the terminal block body 40 to the cooling section 200. Specifically, as illustrated in FIG. 3, the fastening part 50 includes a fastening base 53 and a fastening bolt 58. The fastening base 53 is made of a conductor such as metal and is attached to the central part in the left-right direction of the terminal block body 40. The fastening base 53 penetrates the terminal block body 40 in the up-down direction, and both the upper and lower ends of the fastening base 53 are exposed from the terminal block body 40. A through-hole 54, which extends from the upper surface to the lower surface, is formed in the fastening base 53. Thus, the fastening base 53 is cylindrical with the through-hole 54 formed therein.

A thread hole 204 of the cooling section 200 is provided in the position for mounting the terminal block 60 to the cooling section 200. The fastening bolt 58 is made of a conductor such as metal and is threaded into the thread hole 204 in the state of being inserted through the through-hole 54 of the fastening base 53. As a result, the terminal block 60 is fastened to the cooling section 200.

As illustrated in FIG. 3, the two fastened parts 30L, 30R are configured to be capable of electrically connecting the busbars 10L, 10C, 10R to each other, and capable of fastening the connection parts of the busbars. Specifically, as illustrated in FIG. 1, the two fastened parts 30L, 30R connect the three busbars 10L, 10C, 10R in series in the left-right direction L, R.

As illustrated in FIG. 3, the two fastened parts 30L, 30R are each provided on both sides of the fastening part 50 in the left-right direction L, R. Hereinafter, among the two fastened parts 30L, 30R, the one on the left side is referred to as the “left-side fastened part 30L”, and the one on the right side as the “right-side fastened part 30R”. Additionally, the “left-side fastened part” may also be interchangeably referred to as the “first fastened part”, and the “right-side fastened part” as the “second fastened part”.

The left-side fastened part 30L includes a left-side fastened base 33L and a left-side bolt 38L. The right-side fastened part 30R includes a right-side fastened base 33R and a right-side bolt 38R. The left and right fastened bases 33L, 33R, and the left and right bolts 38L, 38R are all made of a conductor such as metal.

The left-side fastened base 33L is attached to the left end of the terminal block body 40 and penetrates the left end in the up-down direction. Similarly, the right-side fastened base 33R is attached to the right end of the terminal block body 40 and also penetrates the right end in the up-down direction. Consequently, the upper and lower ends of both the left-side fastened base 33L and the right-side fastened base 33R are exposed from the terminal block body 40. The left-side fastened base 33L has a thread hole 34L extending downward from the upper surface. The right-side fastened base 33R has a thread hole 34R extending downward from the upper surface. Thus, the left-side fastened base 33L is cylindrical with the left-side thread hole 34L, and the right-side fastened base 33R is cylindrical with the right-side thread hole 34R.

As illustrated in FIG. 1, among the three busbars 10L, 10C, 10R, the one on the extreme left is referred to as the “left-side busbar 10L”, and the one on the extreme right as the “right-side busbar 10R”. The busbar located between the left-side busbar 10L and the right-side busbar 10R is referred to as the “central busbar 10C”. The “left-side busbar”, “central busbar”, and “right-side busbar” may also be interchangeably referred to as the “first busbar”, “second busbar”, and “third busbar”, respectively.

As illustrated in FIG. 3, both left and right ends of the busbars 10L, 10C, 10R have a through-hole 14 penetrating in the up-down direction. Alternatively, instead of the through-hole, a notch penetrating in the up-down direction may be provided. Hereinafter, the connection part on the right end of the left-side busbar 10L and the left end of the central busbar 10C is referred to as the “left-side busbar connection part cL”, and the connection part on the right end of the central busbar 10C and the left end of the right-side busbar 10R is referred to as the “right-side busbar connection part cR”. Hereinafter, the left-side busbar connection part cL and the right-side busbar connection part cR are collectively referred to as the “left-right busbar connection parts cL, cR”, or simply as the “busbar connection parts cL, cR”.

In the left-side busbar connection part cL, the right end of the left-side busbar 10L and the left end of the central busbar 10C are overlapped vertically. This configuration allows the through-hole 14 at the right end of the left-side busbar 10L and the through-hole 14 at the left end of the central busbar 10C to communicate with each other. Similarly, in the right-side busbar connection part cR, the right end of the central busbar 10C and the left end of the right-side busbar 10R are overlapped vertically. This configuration allows the through-hole 14 at the right end of the central busbar 10C and the through-hole 14 at the left end of the right-side busbar 10R to communicate with each other.

Hereinafter, the state where something is inserted through the through-hole 14 at the right end of the left-side busbar 10L and the through-hole 14 at the left end of the central busbar 10C is referred to as “the state of being inserted through the left-side busbar connection part cL”. Similarly, the state where something is inserted through the through-hole 14 at the right end of the central busbar 10C and the through-hole 14 at the left end of the right-side busbar 10R is referred to as “the state of being inserted through the right-side busbar connection part cR”. Note that “the state of being inserted through the through-holes” in the foregoing phrases may also be interchangeably referred to as “the state of being engaged”.

As illustrated in FIG. 3, the left-side bolt 38L is threaded into the left-side thread hole 34L in the state of being inserted through the left-side busbar connection part cL. As a result, the left-side busbar connection part cL is fastened to the left-side fastened base 33L. The right-side bolt 38R is threaded into the right-side thread hole 34R in the state of being inserted through the right-side busbar connection part cR. As a result, the right-side busbar connection part cR is fastened to the right-side fastened base 33R.

The heat transfer sheets 70L, 70R include a left-side heat transfer sheet 70L and a right-side heat transfer sheet 70R. Both the left and right heat transfer sheets 70L, 70R are made of an insulating material such as resin.

The left-side heat transfer sheet 70L is interposed between the left-side fastened base 33L and the cooling section 200 when the terminal block 60 is fastened to the cooling section 200. This enables the left-side busbar connection part cL to be physically connected to the cooling section 200 via the left-side fastened base 33L and the left-side heat transfer sheet 70L and capable of transferring heat to the cooling section 200. On the other hand, the left-side busbar connection part cL is electrically insulated from the cooling section 200 due to the intervening left-side heat transfer sheet 70L.

Similarly, the right-side heat transfer sheet 70R is interposed between the right-side fastened base 33R and the cooling section 200 when the terminal block 60 is fastened to the cooling section 200. This enables the right-side busbar connection part cR to be physically connected to the cooling section 200 via the right-side fastened base 33R and the right-side heat transfer sheet 70R and capable of transferring heat to the cooling section 200. On the other hand, the right-side busbar connection part cR is electrically insulated from the cooling section 200 due to the intervening right-side heat transfer sheet 70R.

In the present embodiment, the left-side heat transfer sheet 70L and the right-side heat transfer sheet 70R are separate sheets, but they may also be a single continuous sheet.

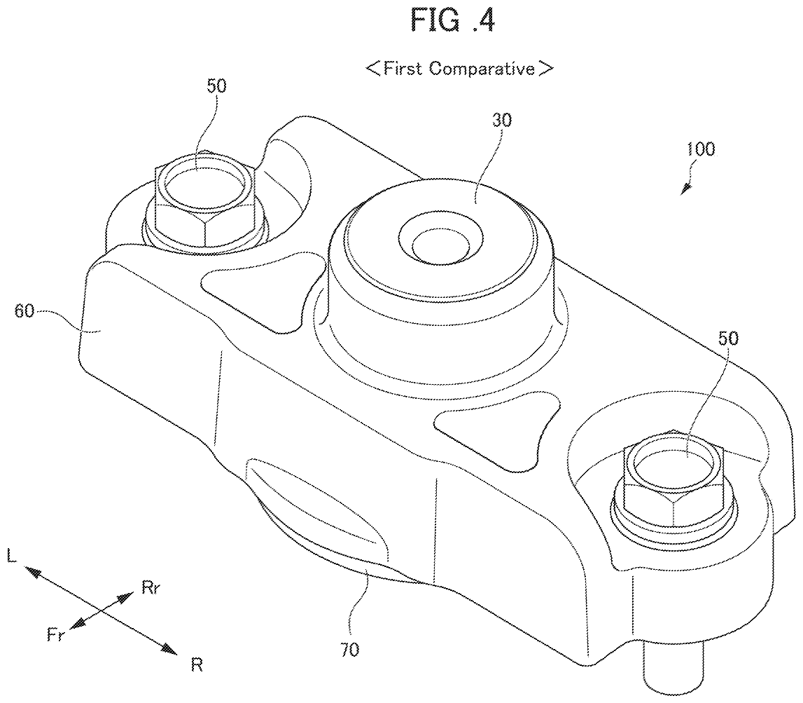

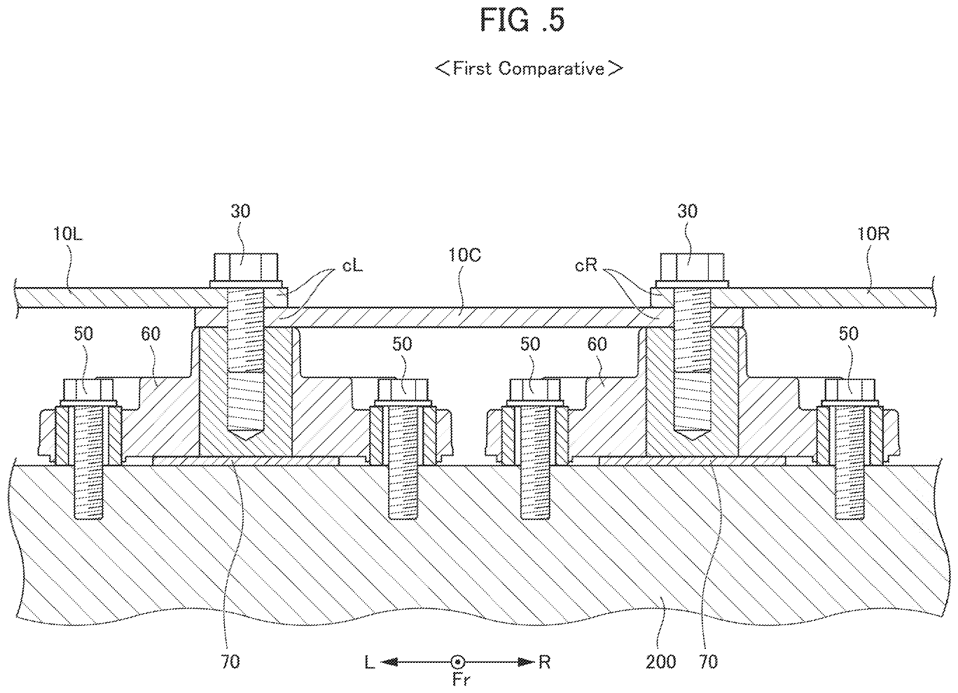

As illustrated in FIG. 4, what follows is referred to as the first comparative example, which is a modification of the present embodiment. Namely, in the first comparative example, instead of the fastening part 50, a fastened part 30 is provided at the central part of the terminal block 60; and instead of the fastened parts 30, fastening parts 50 are provided at both ends of the terminal block 60. Thus, one terminal block 60 includes one fastened part 30 and two fastening parts 50. As illustrated in FIG. 5, a heat transfer sheet 70 is interposed between the fastened part 30 and the cooling section 200 in the central part in left-right direction of the terminal block 60.

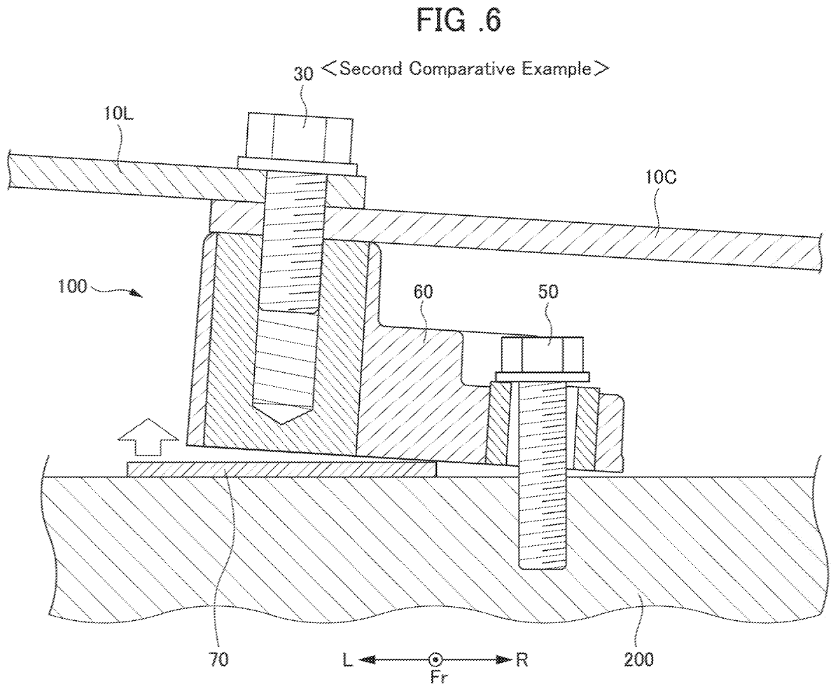

As illustrated in FIG. 6, what follows is referred to as the second comparative example, which is a further modification of the first comparative example. In the second comparative example, no fastening part 50 is provided to the left of the fastened part 30, and only one fastening part 50 is provided to the right of the fastened part 30. Therefore, the counterforce from the heat transfer sheet 70 pushing back the fastened part 30 is applied only from the left side to the fastening part 50.

The following summarizes the configuration and effects of the present embodiment in comparison with the first and second comparative examples as described above.

As illustrated in FIG. 5, in the first comparative example, since there is only one fastened part 30 per terminal block 60, a terminal block 60 is required for each of the busbar connection parts cL, cR. In contrast, in the present embodiment, as illustrated in FIG. 3, since there are two fastened parts 30L, 30R in one terminal block 60, one terminal block 60 is sufficient for two busbar connection parts cL, cR. Therefore, in the present embodiment, half the number of terminal blocks 60 is sufficient compared to the first comparative example. Therefore, the busbar connection structure 100 can be made more compact.

Also, as illustrated in FIG. 5, in the first comparative example, since there are fastening parts 50, 50 on both sides in left-right direction of the fastened part 30, there are two fastening parts 50 for one fastened part 30. Therefore, twice the number of fastening parts 50 as the number of busbar connection parts cL, cR is needed. In contrast, in the present embodiment, as illustrated in FIG. 3, since there is a fastening part 50 between the left and right fastened parts 30L, 30R, there is one fastening part 50 for two fastened parts 30L, 30R. Therefore, one fastening part 50 is sufficient for two busbar connection parts cL, cR. Thus, in the present embodiment, only a quarter of the number of fastening parts 50 is needed compared to the first comparative example.

Therefore, in this respect as well, the busbar connection structure 100 can be made more compact.

Furthermore, as illustrated in FIG. 5, in the first comparative example, since there are two fastening parts 50 in one terminal block 60, it is not possible to freely adjust the installation angle of the terminal block 60. In contrast, in the present embodiment, as illustrated in FIG. 3, since there is one fastening part 50 for one terminal block 60, the installation angle of the terminal block 60 can be freely adjusted around the fastening part 50. Therefore, the busbar connection structure 100 is more user-friendly.

As illustrated in FIG. 6, in the second comparative example, the fastening part 50 is provided only to the right of the fastened part 30. Therefore, compared to the first comparative example, the number of fastening parts 50 can be halved. However, the counterforce from the heat transfer sheet 70 pushing back the fastened part 30L is applied unbalanced to the left and right of the terminal block 60. This makes the terminal block 60 more prone to tilting or warping.

In contrast, in the present embodiment, as illustrated in FIG. 3, there are fastened parts 30L, 30R on both sides of the fastening part 50, and heat transfer sheets 70L, 70R are interposed between each of the left and right fastened parts 30L, 30R and the cooling section 200. Therefore, the counterforce from the heat transfer sheets 70 pushing back the fastened parts 30L, 30R is applied evenly to both sides of the terminal block 60. This helps prevent the terminal block 60 from tilting or warping.

As illustrated in FIG. 3, the left and right fastened parts 30L, 30R include fastened bases 33L, 33R, and bolts 38L, 38R, respectively. Therefore, the left and right fastened parts 30L, 30R can be realized with such simple structures including the fastened bases 33L, 33R and the bolts 38L, 38R.

As illustrated in FIG. 3, the left-side fastened part 30L fastens the right end of the left-side busbar 10L and the left end of the central busbar 10C. The right end of the central busbar 10C and the left end of the right-side busbar 10R are fastened to the right-side fastened part 30R. Therefore, three busbars 10L, 10C, 10R can be connected in series using one terminal block 60.

### Other Embodiments

The embodiments described above can be modified, for example, in the following manner. In the present embodiment, as illustrated in FIG. 1, three busbars 10L, 10C, 10R are connected in series using a single terminal block 60. However, two sets of busbars, each set including two out of the four busbars, may be connected in parallel using a single terminal block 60. For instance, the connection part of the two busbars lying side by side in the front-back direction Fr, Rr on the left side may be fastened to the left-side fastened part 30L, and the connection part of the two busbars lying side by side in the front-back direction Fr, Rr on the right side may be fastened to the right-side fastened part 30R.

### EXPLANATION OF REFERENCE NUMERALS

10L: left-side busbar (first busbar)
10C: central busbar (second busbar)
10R: right-side busbar (third busbar)
30L: left-side fastened part (first fastened part)
30R: right-side fastened part (second fastened part)
33L: left-side fastened base
33R: right-side fastened base
34L: left-side thread hole
34R: right-side thread hole
38L: left-side bolt
38R: right-side bolt
40: terminal block body
50: fastening part
60: terminal block
70L: left-side heat transfer sheet
70R: right-side heat transfer sheet
100: busbar connection structure
200: cooling section

What is claimed is:

1. A busbar connection structure that electrically connects a plurality of busbars to each other, and connects connection parts of the busbars to a cooling section in a heat transferable manner while electrically insulating the connection parts of the busbars from a cooling section, the busbar connection structure comprising:
a terminal block body as an insulator;
a fastening part that fastens the terminal block body to the cooling section;
a first fastened part as a conductor attached to one of both sides of the fastening part in the terminal block body, so as to be exposed to outside of the terminal block body, the first fastened part having the connection part of the plurality of busbars fastened thereto;
a second fastened part as a conductor attached to another of the both sides, so as to be exposed to outside of the terminal block body, the second fastened part having the connection part of the plurality of busbars fastened thereto; and
a heat transfer sheet as an insulator interposed between both the first fastened part and the cooling section, and between the second fastened part and the cooling section.

2. The busbar connection structure according to claim 1, wherein
each of the fastened parts includes a fastened base as a conductor attached to the terminal block body, and a bolt; the fastened base includes a thread hole; and the connection part is fastened to the fastened part by threading the bolt into the thread hole in a state where the bolt is engaged with the connection part.

3. The busbar connection structure according to claim 1, wherein
the plurality of busbars include a first busbar, a second busbar, and a third busbar,
a tip end of the first busbar and a base end of the second busbar are fastened to the first fastened part, and
a tip end of the second busbar and a base end of the third busbar are fastened to the second fastened part.
